(19) United States
(12) Patent Application Publication
(10) Pub. No.: US 2026/0253549 A1
(43) Pub. Date: Aug. 27, 2026

(54) SHIFT REGISTER UNIT, GATE DRIVE CIRCUIT AND DISPLAY DEVICE

(71) Applicant: Everdisplay Optronics (Shanghai) Co., Ltd., Shanghai (CN)

(72) Inventors: Ying-Hsiang TSENG, Shanghai (CN); Lina XIAO, Shanghai (CN)

(73) Assignee: Everdisplay Optronics (Shanghai) Co., Ltd., Shanghai (CN)

(21) Appl. No.: 18/728,088

(22) PCT Filed: Apr. 17, 2023
(86) PCT No.: PCT/CN2023/088639

§ 371 Date: Jul. 11, 2024

(30) Foreign Application Priority Data
Mar. 27, 2023 (CN) 202310315111.0

(51) Int. Cl. G09G 3/3266; G11C 19/28

(52) U.S. Cl. CPC G09G 3/3266; G09G 2310/0286; G09G 2310/08; G09G 2330/021; G09G 2340/0435

(57) ABSTRACT

The present disclosure provides a shift register unit, a gate drive circuit and a display device. The shift register unit includes an input module, a first control module, a second control module, a third control module, a first output module, a second output module, a first capacitor and a second capacitor. The second output module can be turned off by the third control module, and only the first output module is turned on, so that the shift register unit continuously outputs a high-level signal.

### CROSS REFERENCE TO RELATED APPLICATION

The present application is a U.S. National Stage of International Application No. PCT/CN 2023/088639, filed on Apr. 17, 2023, which claims the benefit of priority to Chinese Application No. 202310315111.0, filed on Mar. 27, 2023, both of which are incorporated by reference herein in their entireties for all purposes.

### TECHNICAL FIELD

The present disclosure relates to the field of display technology, and in particular to a shift register unit, a gate drive circuit and a display device.

### BACKGROUND

The display device includes not only a display panel, but also a gate drive circuit (also called a row drive circuit, Gate Driver) and a source drive circuit (also called a column drive circuit, Source Driver) for controlling the display of the display panel with a pixel array. The display panel adopts progressive scanning display mode, in which the gate drive circuit is configured to generate a scanning signal to turn on each row of pixels in turn, and the source drive circuit is configured to provide a data signal to a row of pixels when it is turned on to realize the display of pixels.

The gate drive circuit includes a shift register. The shift register includes a plurality of cascaded shift register units. Each stage of the shift register unit is usually mainly composed of several transistors. A clock signal CKV and an input signal STV/in (that is, a start pulse signal) are input to the circuit, and a level signal (that is, a Gout signal) is output at the output end.

Mobile display devices have high requirements for power consumption, and the proportion of power consumption of the display screen is particularly important. The refresh rate of the display screen directly affects the power consumption. Although the low refresh rate has lower power consumption, the low refresh rate dynamic display effect seriously affects the display quality. Therefore, it is urgent to study the low power consumption of the display screen without affecting the display effect.

### SUMMARY

The embodiment of the present disclosure provides a shift register unit, including:
an input module, configured to transmit an input signal of an input signal terminal to a first node in response to a first clock signal;
a first control module, configured to transmit a first voltage signal to the first node in response to a second clock signal;
a second control module, configured to transmit a second voltage signal to a second node in response to the first clock signal;
a first output module, configured to transmit the first voltage signal to an output signal terminal in response to a signal of the second node;
a second output module, configured to transmit the second clock signal to the output signal terminal in response to a signal of the first node;
a third control module, configured to transmit the first clock signal to the second node, or to transmit the first voltage signal to the first node in response to a control clock signal;
a first capacitor, connected between the first node and the output signal terminal; and
a second capacitor, connected between the first voltage signal terminal and the second node.

The embodiment of the present disclosure provides a gate drive circuit, including a shift register unit according to any one of the above items.

The embodiment of the present disclosure provides a display device, including a gate drive circuit described above.

### BRIEF DESCRIPTION OF THE DRAWINGS

By reading the detailed description of the non-limiting embodiments with reference to the following figures, other features, purposes and advantages of the present disclosure will become more apparent.

FIG. 1 is a circuit diagram of a shift register unit of an embodiment of the present disclosure;

FIG. 2 is a schematic diagram of a gate drive circuit of an embodiment of the present disclosure;

FIG. 3 is a timing waveform diagram of a gate drive circuit of an embodiment of the present disclosure;

FIG. 4 is a schematic diagram of a display panel including a dynamic (high refresh) display area and a static (low refresh) display area in the prior art;

FIG. 5 is a circuit diagram of the display panel of FIG. 4;

FIG. 6 is a timing waveform diagram corresponding to the shift register unit of the dynamic display area of an embodiment of the present disclosure;

FIG. 7 is an equivalent circuit diagram of the shift register unit of an embodiment of the present disclosure corresponding to FIG. 6.

FIG. 8 is a timing waveform diagram of a shift register unit in a static display area of an embodiment of the present disclosure corresponding to the first time period;

FIG. 9 is an equivalent circuit diagram of a shift register unit of an embodiment of the present disclosure corresponding to FIG. 8;

FIG. 10 is a timing waveform diagram of a shift register unit in a static display area of an embodiment of the present disclosure corresponding to the second time period;

FIG. 11 is an equivalent circuit diagram of a shift register unit in an embodiment of the present disclosure corresponding to FIG. 10;

FIG. 12 is a timing waveform diagram of a shift register unit in a static display area of an embodiment of the present disclosure corresponding to the third time period;

FIG. 13 is an equivalent circuit diagram of a shift register unit in an embodiment of the present disclosure corresponding to FIG. 12;

FIG. 14 is a circuit diagram of a shift register unit of another embodiment of the present disclosure;

FIG. 15 is a timing waveform diagram corresponding to FIG. 14.

### REFERENCE NUMERALS

1 input module
2 first control module
3 second control module
4 first output module
5 second output module
6 third control module
CKV1 first clock signal
CKV2 second clock signal
CKV3 third clock signal
CKV4 fourth clock signal
VGH first voltage signal
VEE second voltage signal
STV/in input signal
Gout output signal
C1 first capacitor
C2 second capacitor
SR1~SR4 first-stage shift register unit~fourth-stage shift register unit

### DETAILED DESCRIPTION

The example embodiments will now be described more fully with reference to the accompanying drawings. However, the example embodiments can be implemented in a variety of forms and should not be construed as limited to the embodiments set forth herein; rather, these embodiments are provided so that the present disclosure will be comprehensive and complete and the concepts of the example embodiments will be fully conveyed to those skilled in the art. The same reference numerals in the figures represent the same or similar structures, and thus their repeated descriptions will be omitted. “or” in the specification may both means “and” or “or”.

In addition, it should be understood by those of ordinary skill in the art that the drawings are only schematic illustrations of the present disclosure and are not necessarily drawn to scale.

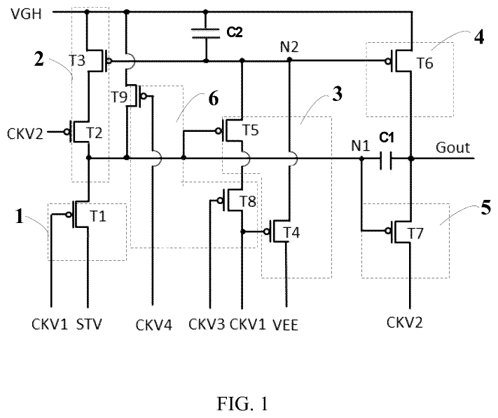

To solve the problems of the prior art, embodiments of the present disclosure provide a shift register unit, as shown in FIG. 1, the shift register unit includes:
an input module 1, configured to transmit an input signal STV of an input signal terminal to a first node N1 in response to a first clock signal CKV1;
a first control module 2, configured to transmit a first voltage signal VGH to a first node N1 in response to a second clock signal CKV2;
a second control module 3, configured to transmit a second voltage signal VEE to a second node N2 in response to the first clock signal CKV1;
a first output module 4, configured to transmit the first voltage signal VGH to an output signal terminal in response to the signal of the second node N2;
a second output module 5, configured to transmit the second clock signal CKV2 to the output signal terminal in response to the signal of the first node N1;
a third control module 6, configured to transmit the first clock signal CKV1 to the second node N2, or to transmit the first voltage signal VGH to the first node N1 in response to the control clock signal;
a first capacitor C1 connected between the first node N1 and the output signal terminal; and
a second capacitor C2 connected between the first voltage signal VGH terminal and the second node N2;
wherein, the first clock signal CKV1 and the second clock signal CKV2 have the same frequency and opposite phases. The first voltage signal VGH is a positive voltage signal, and the second voltage signal VEE is a negative voltage signal.

The present disclosure can turn off the second output module through the third control module, and only turn on the first output module, so that the shift register unit continues to output a high-level signal. The gate drive circuit formed by the shift register unit provided by the present disclosure can dynamically adjust the refresh rate of each region of the display area of the display device. When there are dynamic display areas and static display areas in the display area, the shift register unit of the dynamic display area maintains a high refresh rate; the shift register unit of the static display area continuously outputs a high-level signal through the third control module to maintain the frame data of the previous frame unchanged, reduce the refresh rate of the low-refresh display area, and reduce the power consumption of the display device without affecting the display effect of the display device.

Please refer to FIG. 1 again. The input module 1 includes a first transistor T1. the control terminal of the first transistor Tl is connected to the first clock signal CKV1 line. The first terminal of the first transistor Tl is connected to the input signal terminal, and the second terminal of the first transistor Tl is connected to the first node N1. The first control module 2 includes a second transistor T2 and a third transistor T3. The control terminal of the second transistor T2 is connected to the second clock signal CKV2 line, and the second terminal of the second transistor T2 is connected to the first node N1. The control terminal of the third transistor T3 is connected to the second node N2, the first terminal of the third transistor T3 is connected to the first voltage signal VGH line, and the second terminal of the third transistor T3 is connected to the first terminal of the second transistor T2. The second control module 3 includes a fourth transistor T4 and a fifth transistor T5. The control terminal of the fourth transistor T4 is connected to the first clock signal CKV1 line, the first terminal of the fourth transistor T4 is connected to the second voltage signal VEE line, and the second terminal of the fourth transistor T4 is connected to the second node N2. The control terminal of the fifth transistor T5 is connected to the first node N1, the first terminal of the fifth transistor T5 is connected to an output terminal of the third control module 6, and the second terminal of the fifth transistor T5 is connected to the second node N2. The first output module 4 includes a sixth transistor T6. The control terminal of the sixth transistor T6 is connected to the second node N2, the first terminal of the sixth transistor T6 is connected to the first voltage signal VGH line, and the second end of the sixth transistor T6 is connected to the output signal terminal. The second output module 5 includes a seventh transistor T7. The control terminal of the seventh transistor T7 is connected to the first node N1, the first terminal of the seventh transistor T7 is connected to the second clock signal CKV2 line, and the second terminal of the seventh transistor T7 is connected to the output signal terminal. The third control module 6 includes an eighth transistor T8 and a ninth transistor T9, and the control clock signal includes a third clock signal CKV3 and a fourth clock signal CKV4. The control terminal of the eighth transistor T8 is connected to the third clock signal CKV3 line, the first terminal of the eighth transistor T8 is connected to the first clock signal CKV1 line, and the second terminal of the eighth transistor T8 is connected to the first terminal of the fifth transistor T5. The control terminal of the ninth transistor T9 is connected to the fourth clock signal CKV4 line, the first terminal of the ninth transistor T9 is connected to the first voltage signal VGH line, and the second terminal of the ninth transistor T9 is connected to the first node N1.

In the high refresh display area, the third clock signal CKV3 is at a low level, and the fourth clock signal CKV4 is at a high level; the output of the row scanning signal of the high refresh display area is controlled.

In the first phase of the low refresh display area, the first clock signal CKV1 is at a low level, the second clock signal CKV2 is at a high level, the third clock signal CKV3 is set to a high level, and the fourth clock signal CKV4 is at a high level; the row scanning signal of the low refresh display area is controlled to output a high-level signal.

In the second phase of the low refresh display area, the first clock signal CKV1 is at a high level, the second clock signal CKV3 is a low level, the third clock signal CKV4 is at a high level, and the fourth clock signal CKV4 is at a low level; the row scanning signal of the low refresh display area is controlled to continuously output a high-level signal.

In this embodiment, the first transistor T1 to the ninth transistor T9 are all PMOS transistors. The control terminal of the PMOS transistor is a gate, the first terminal of the PMOS transistor is a source, and the second terminal of the PMOS transistor is a drain. The on level of the PMOS transistor is a low level, and the off level of the PMOS transistor is a high level.

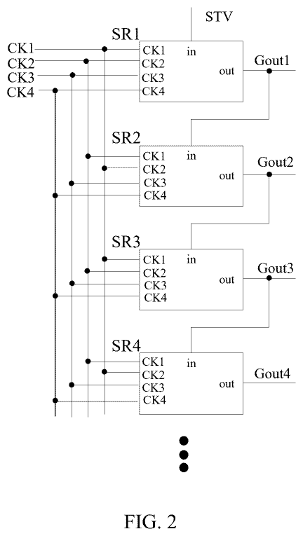

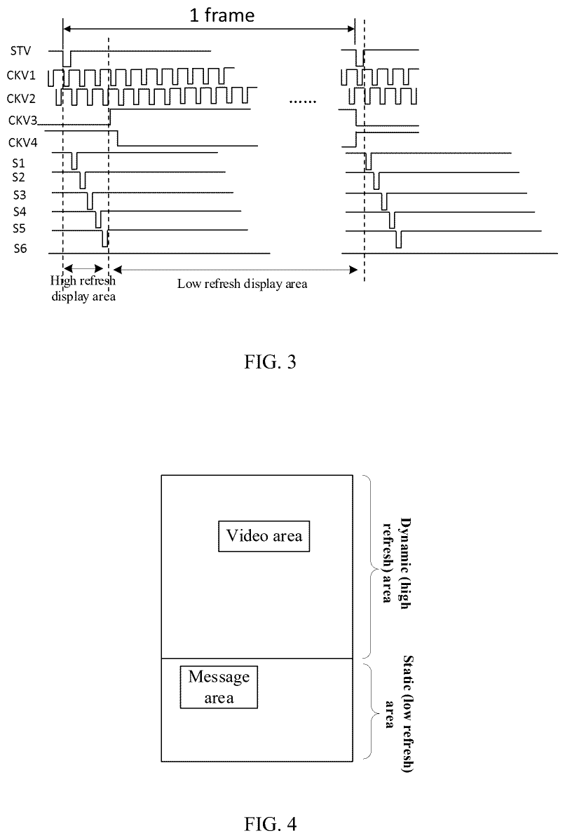

As shown in FIG. 2, an embodiment of the present disclosure further provides a gate drive circuit, including the shift register unit as described above. The gate drive circuit includes a plurality of the above-mentioned shift register units. The plurality of shift register units are electrically connected in a cascade manner. The input terminal of the first-stage shift register unit is connected to a low-level start pulse signal. The signal at the output signal terminal of each stage of the shift register unit except the last stage of the shift register unit is connected to the input signal terminal of the next stage of the shift register unit. As shown in FIG. 3, it is a timing waveform diagram corresponding to the gate drive circuit shown in FIG. 2. The clock signals CK1 and CK2 are square wave pulses with the same period and opposite phases. The input signal STV is a low-level pulse signal. S1~S6 are waveform diagrams of the output signals of the first-stage to the sixth-stage shift register units, respectively.

Specifically, in this embodiment, four cascaded shift register units are taken as an example. The input signal at the input signal terminal of the first-stage shift register unit SR1 is a start pulse signal, represented by STV; the output signal Gout1 of the first-stage shift register unit SR1 is configured as the input signal of the second-stage shift register unit SR2, represented by in; the output signal Gout2 of the second-stage shift register unit SR2 is configured as the input signal of the third-stage shift register unit, represented by in; the output signal Gout3 of the third-stage shift register unit SR3 is configured as the input signal of the fourth-stage shift register unit, represented by in. In this way, after a low-level start pulse signal STV is input to the input signal terminal of the first-stage shift register unit SR1, a stable output signal Gout1 can be generated at its output signal terminal, and this output signal Gout1 is input to the input signal terminal of the second-stage shift register unit SR2 . . . Repeat this to obtain output signals Gout1, Gout2, Gout3 and Gout4 at the output terminals of the four-stage shift register units.

As shown in FIG. 2, the gate drive circuit may further include a clock signal generating unit (not shown in the figure). The clock signal generating unit is configured to generate a first clock signal CKV1, a second clock signal CKV2, a third clock signal CKV3 and a fourth clock signal CKV4. Specifically, the first clock signal CKV1 and the second clock signal CKV2 in the first shift register SR1 are respectively the first clock signal CKV1 and the second clock signal CKV2 generated by the clock signal generating unit; the first clock signal CKV1 and the second clock signal CKV2 in the second shift register unit SR2 are respectively the second clock signal CKV2 and the first clock signal CKV1 generated by the clock signal generating unit; the first clock signal CKV1 and the second clock signal CKV2 in the third shift register unit SR3 are respectively the first clock signal CKV1 and the second clock signal CKV2 generated by the clock signal generating unit; the first clock signal CKV1 and the second clock signal CKV2 in the fourth shift register unit SR4 are respectively the second clock signal CKV2 and the first clock signal CKV1 generated by the clock signal generating unit; and so on, the first clock signal CKV1 and the second clock signal CKV2 in the n-th shift register unit SRn are respectively the first clock signal CKV1 and the second clock signal CKV2 generated by the clock signal generating unit; the first clock signal CKV1 and the second clock signal CKV2 in the (n+1)-th shift register unit are respectively the second clock signal CKV2 and the first clock signal CKV1 generated by the clock signal generating unit. The third clock signal CKV3 and the fourth clock signal CKV4 of each stage of shift register unit are respectively the third clock signal CKV3 and the fourth clock signal CKV4 generated by the clock signal generating unit. Before the clock signal generating unit generates the third clock signal CKV3 and the fourth clock signal CKV4, the integrated circuit chip compares the display data of the previous frame before the current frame is displayed, and locates the position in the display area that does not need to be updated, and the clock signal generating unit determines the signal level of the third clock signal CKV3 and the fourth clock signal CKV4. As shown in FIG. 3, in the high refresh display area, the third clock signal CKV3 generated by the clock signal generating unit is a low-level signal, and the fourth clock signal CKV4 generated by the clock signal generating unit is at a high level signal; in the low refresh display area, the third clock signal CKV3 generated by the clock signal generating unit changes from a low level to a high level, and the fourth clock signal CKV4 generated by the clock signal generating unit first keeps the high level unchanged, and then changes from a high level to a low level.

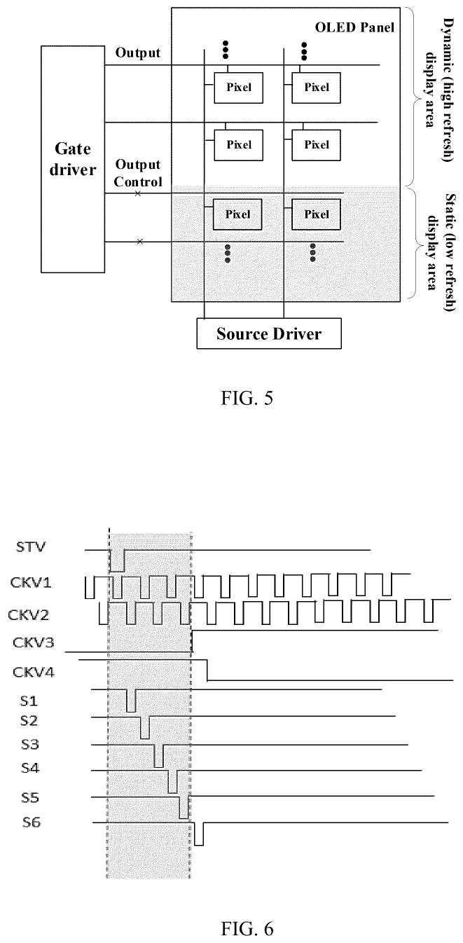

As shown in FIG. 4 and FIG. 5, a display device is also provided in an embodiment of the present disclosure, including the gate drive circuit described above, and the gate scan lines in the display device are turned on row by row with the signals output from the shift register units, that is, the signal output from the output signal terminal of each shift register unit is the gate scan line signal of each row of pixel units. Furthermore, the display device also includes a source drive circuit for providing a data voltage to the corresponding pixel unit when the gate scan line is turned on. As shown in FIG. 4, the display area of the display device includes a dynamic (high refresh) display area and a static (low refresh) display area. The dynamic display area has a high refresh rate, also called a high refresh display area, such as a video playback area, etc. The static display area has a low refresh rate, also called a low refresh display area, such as a message area, etc. The gate drive circuit provided by the present disclosure can dynamically adjust the refresh rate of each region of the display area of the display device. When the row scanning signal of the progressive scanning reaches the low refresh display area, the shift register unit that outputs the row scanning signal of the low refresh display area continuously outputs the row scanning signal as a high level through the third control module, so that the pixels in the low refresh display area maintain the data voltage of the previous frame unchanged. That is, the frame data of the previous frame is maintained without updating. The display screen of the low refresh display area remains unchanged, the refresh frequency of the low refresh display area is reduced, and the power consumption of the display device is reduced. The screen of the high refresh display area maintains a high refresh frequency, and the screen of the low refresh display area maintains a low refresh frequency. Therefore, the present disclosure can reduce the power consumption of the display device without affecting its display effect.

The working principle of the gate drive circuit in this example embodiment is described in more detail below in conjunction with the driving timing diagrams in FIG. 6 to FIG. 13 and the equivalent circuit diagrams corresponding to each phase. In this example embodiment, S1 to S5 are the gate scanning signal timing diagrams of the high refresh display area, and S6 is the gate scanning signal timing diagram of the low refresh display area.

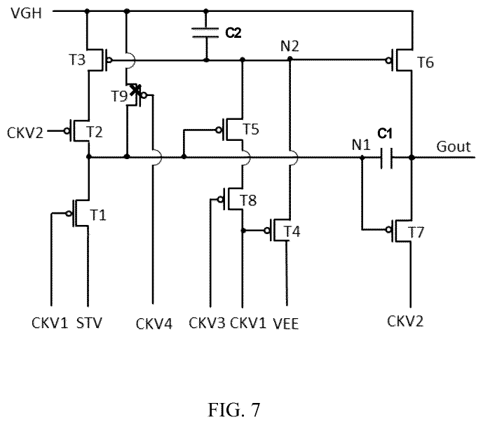

In the high refresh display area, taking the first shift register unit SR1 as an example, the working principle of each stage of shift register unit in the high refresh display area is introduced. Referring to FIG. 6 and FIG. 7, in the charging phase of the first shift register unit SR1, the input signal STV is a low-level signal, the first clock signal CKV1 is a low-level signal, the second clock signal CKV2 is a high-level signal, the third clock signal CKV3 is a low-level signal, and the fourth clock signal CKV4 is a high-level signal. At this time, the second transistor T2 and the ninth transistor T9 are turned off, and the first transistor T1, the fourth transistor T4 and the eighth transistor T8 are turned on. The input signal STV is transmitted to the first node N1 through the first transistor T1. The seventh transistor T7 and the fifth transistor T5 are turned on, and the second clock signal CKV2 is transmitted to the output signal terminal through the seventh transistor T7, thereby charging the first capacitor C1. The second voltage signal VEE is transmitted to the second node N2 through the fourth transistor T4 to reset the potential of the second node N2. The first clock signal CKV1 is transmitted to the second capacitor C2 through the fifth transistor T5 to charge the second capacitor C2. Under the action of the low-level signal stored in the second capacitor C2, the second node N2 is at a low level at this time, thereby turning on the sixth transistor T6, and the first voltage signal VGH is transmitted to the output signal terminal through the sixth transistor T6. Since the second clock signal CKV2 and the first voltage signal VGH are at a high level at this phase, the output signal Gout1 of the output signal terminal is a high-level signal at this time.

Continuing to refer to FIG. 6 and FIG. 7, the first-stage shift register SR1 is in the output phase. At this time, the input signal STV, the first clock signal CKV1 and the fourth clock signal CKV4 are high-level signals, and the second clock signal CKV2 and the third clock signal CKV3 are low-level signals. At this time, the first transistor T1, the fourth transistor T4 and the ninth transistor T9 are turned off. Under the action of the low-level signal stored in the first capacitor C1, the first node NI is at a low level. At this time, the fifth transistor T5 and the seventh transistor T7 are turned on, and the first clock signal CKV1 is transmitted to the second node N2 through the eighth transistor T8 and the fifth transistor T5. At this time, the second node N2 is at a high level, and the sixth transistor T6 is turned off. The second clock signal CKV2 is transmitted to the output signal terminal through the seventh transistor T7. Therefore, at this time, the output signal Gout1 at the output signal terminal of the first-stage shift register unit is a low-level signal, and the first gate scanning signal S1 is output as a low-level signal at this time. The low-level first gate scanning signal S1 will drive the corresponding pixel unit through the first gate scan line to refresh the display.

The working principle of the subsequent phase of the first-stage shift register SR1 is the same as shown above, and will not be repeated here. After the first-stage shift register SR1 outputs a low-level signal, a high-level signal is continuously output in the subsequent phase, and the high-level signal in the subsequent phase can no longer refresh the corresponding pixel unit to refresh the display.

Further, the low-level signal output by the first gate scanning signal S1 will also be configured as the input signal “in” of the input signal terminal of the second-stage shift register SR2, charging the first capacitor C1 and the second capacitor C2 in the second-stage shift register SR2, and completing the signal output of the output signal terminal. The working principle of the second-stage shift register SR2 is the same as the above-mentioned first-stage shift register unit SR1, and will not be repeated here. Similarly, the working principles of the third-stage shift register SR3, the fourth-stage shift register SR4 and the fifth-stage shift register SR5 are the same as the first-stage shift register SR1, and the low-level third scanning signal S3, the low-level fourth scanning signal S4 and the low-level fifth scanning signal S5 are output in sequence, and the pixel units connected to each gate scan line are refreshed in sequence, and the row scan display of each high refresh display area is completed in sequence.

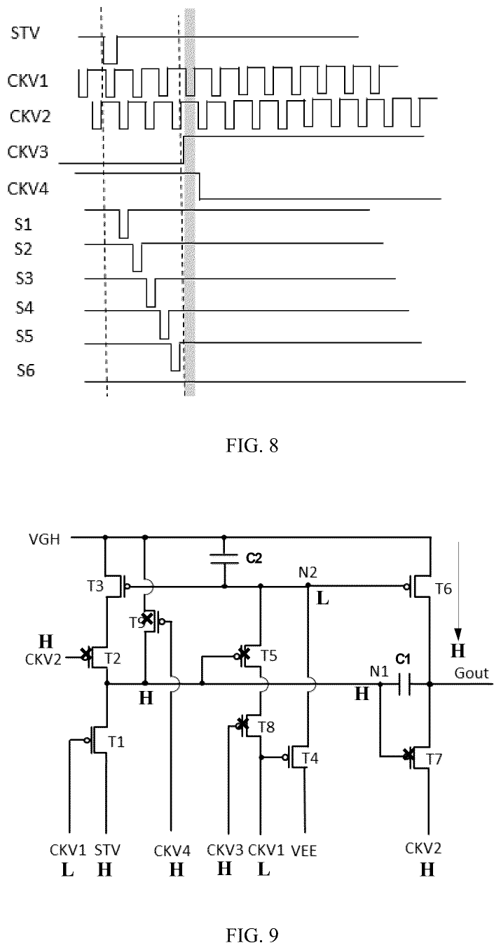

As shown in FIG. 8 and FIG. 9, in the first time period of the low refresh display area, when the fifth scanning signal S5 is at a low level, the sixth-stage shift register unit SR6 charges the first capacitor C1 and the second capacitor C2, and at this time the output signal of SR6 is a high-level signal. In order to make the sixth-stage shift register SR6 output a high-level signal, at this time the third clock signal CKV3 changes from a low level to a high level, the first clock signal CKV1 of the sixth-stage shift register is at a low level, and the second clock signal CKV2, the third clock signal CKV3, and the fourth clock signal CKV4 remain high-level signals. Therefore, the first transistor T1 and the fourth transistor T4 are turned on, and the second transistor T2, the seventh transistor T7, the eighth transistor T8, and the ninth transistor T9 are turned off. The second voltage signal VEE is transmitted to the second node N2 through the fourth transistor T4. At this time, the second node N2 is at a low level, the sixth transistor T6 is turned on, and the first voltage signal VGH is transmitted to the output signal terminal through the sixth transistor T6, and the second capacitor C2 is charged. At this time, the signal output terminal of the sixth-stage shift register SR6 outputs a high-level signal, that is, S6 outputs a high-level signal. At this time, the data in the low-refresh display area maintains the previous frame without updating, the refresh frequency in the low-refresh display area is reduced, and the power consumption of the display area is reduced. By converting the third clock signal CKV3 to a high-level signal, the second node N2 maintains a low potential, and the fourth clock signal CKV4 is converted to a low level. Thus, the first node N1 clock maintains a high level, the seventh transistor T7 is turned off, and the output signal of the output signal terminal outputs the first voltage signal VGH, that is, a high-level signal. The shift register unit outputs a high-level signal, so that the display data in the low-frequency refresh area does not change, the display image of the previous frame is maintained, the refresh rate of the low-refresh display area is reduced, and the power consumption of the display screen is reduced.

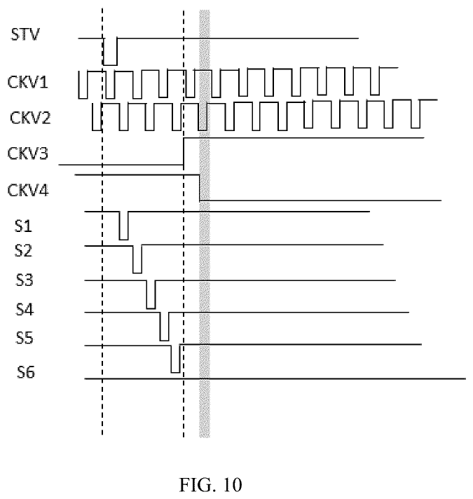

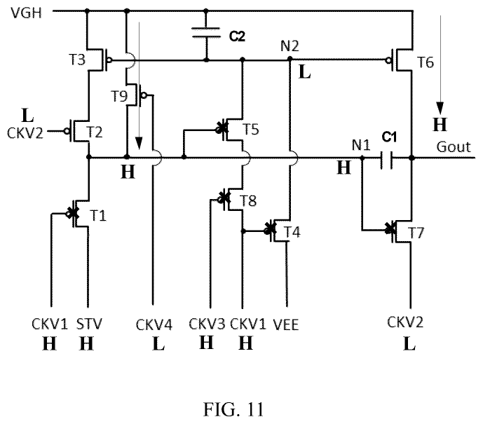

As shown in FIG. 10 and FIG. 11, when entering the second time period of the low refresh display area, the first clock signal CKV1 changes from a low level to a high level, the second clock signal CKV2 changes from a high level to a low level, the third clock signal CKV3 maintains a high level, and the fourth clock signal CKV4 changes to a low level. The duration of the second time period is equal to the time that the second clock signal CKV2 maintains a high level in each cycle. Therefore, the first transistor T1, the fourth transistor T4 and the eighth transistor T8 are turned off, and the second transistor T2 and the ninth transistor T9 are turned on. The first voltage signal VGH is transmitted to the first node N1 through the ninth transistor T9, so the first node N1 is at a high level at this time. Under the action of the high level of the first node N1, the fifth transistor T5 and the seventh transistor T7 are turned off. Under the action of the low-level signal stored in the first capacitor C1, the second node N2 is at a low level, the third transistor T3 and the sixth transistor T6 are turned on. The first voltage signal VGH is transmitted to the first node N1 through the third transistor T3 and the second transistor T2 in turn, and the first voltage signal VGH is transmitted to the first node N1 through the ninth transistor T9, so that the first node NI continues to maintain a high level. The first voltage signal VGH is transmitted to the signal output terminal through the sixth transistor T6, and the output signal Gout of the signal output terminal is at a high level. The output high-level signal makes the sixth gate scanning signal S6 high, so that the pixel units of the display area connected to S6 maintain the previous frame without updating, and the power consumption is reduced.

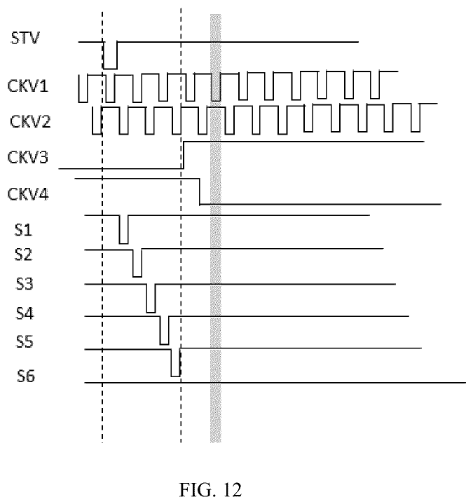

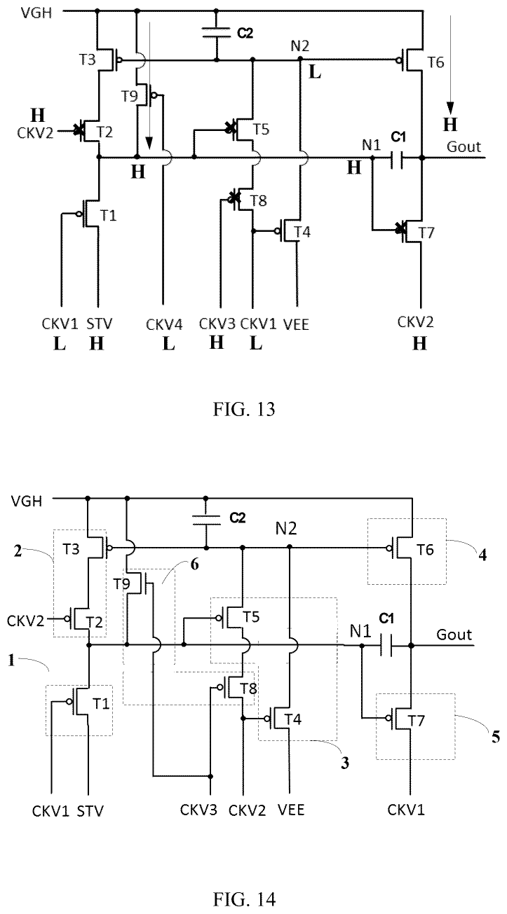

As shown in FIG. 12 and FIG. 13, entering the third time period of the low-refresh display area, the first clock signal CKV1 changes from a high level to a low level, the second clock signal CKV2 changes from a low level to a high level, the third clock signal CKV3 maintains a high level, the fourth clock signal CKV4 maintains a low level, and STV is at a high level. At this time, the first transistor T1, the fourth transistor T4 and the ninth transistor are turned on, and the second transistor T2 and the eighth transistor T8 are turned off. The input signal STV is transmitted to the first node N1 through the first transistor T1, at which time the first node NI is at a high level and the seventh transistor T7 is turned off. The second voltage signal VEE is transmitted to the second node N2 through the fourth transistor T4 to charge the first capacitor C1, and at this time the second node N2 is at a low level, and the sixth transistor T6 is turned on. The first voltage signal VGH is transmitted to the output terminal Gout through the sixth transistor T6, and at this time the output signal Gout is at a high level. The second time period and the third time period are repeated for subsequent phases.

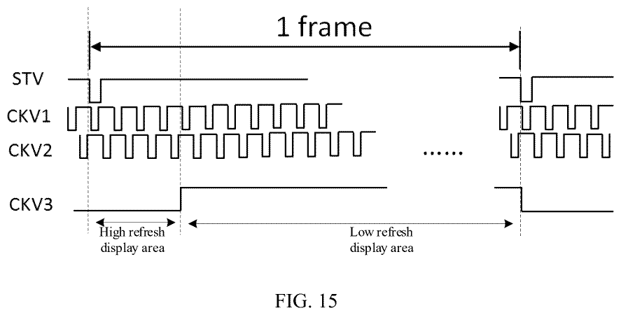

As shown in FIG. 14 and FIG. 15, a circuit diagram of another shift register unit provided in the embodiment of the present application and the timing waveform diagram corresponding to the gate drive circuit formed therefrom are illustrated. The difference from those in embodiment 1 lies in that, the third control module 6 in this embodiment is only provided with a control clock signal. That is, the third clock signal line and the fourth clock signal line are realized through the same signal line. The reduction of clock signals can reduce the difficulty of arranging the gate drive circuit and simplify the process of the drive circuit. Referring to FIG. 14 and FIG. 15 again, in this embodiment, the third control module 6 includes an eighth transistor T8 and a ninth transistor T9, and the control clock signal includes a third clock signal CKV3.

The control terminal of the eighth transistor T8 is connected to the third clock signal CKV3, the first terminal of the eighth transistor T8 is connected to the first clock signal CKV1, and the second terminal of the eighth transistor T8 is connected to the first clock signal CKV1.

The control terminal of the ninth transistor T9 is connected to the third clock signal CKV3, the first terminal of the ninth transistor T9 is connected to the first voltage signal VGH, and the second terminal of the ninth transistor T9 is connected to the first node N1.

The first transistor T1 to the seventh transistor T7 are PMOS transistors. The eighth transistor T8 and the ninth transistor T9 are NMOS transistors. The eighth transistor T8 and the ninth transistor T9 adopt CMOS technology.

In the high-frequency refresh display area, the third clock signal CKV3 is maintained as a low-level signal, the eighth transistor T8 and the ninth transistor T9 are maintained in a turned off state. The working principle of each stage of the shift register in the high-frequency refresh display area is the same as the above-mentioned embodiment, which will not be repeated here. In the low-frequency refresh display area, the third clock signal CKV3 changes from a high level to a low level. At this time, the eighth transistor T8 and the ninth transistor T9 are turned on, and the first voltage signal VGH is transmitted to the first node N1 through the ninth transistor T9 to turn off the seventh transistor T7. At this time, the output signal of the shift register unit in the low-frequency refresh display area is only related to the sixth transistor T6 of the first output module. The first voltage signal VGH continues to output a high-level signal through the sixth transistor T6. The shift register in the low-frequency refresh display area maintains a high-level signal, and the data is not updated. The data of the previous frame is maintained, the row scanning frequency in the display area is reduced, the refresh rate in the display area is reduced, and the power consumption of the display area is reduced.

In some other embodiments, those skilled in the art can easily conclude that the shift register unit provided by the present disclosure can be easily changed to all N-type transistors. Or, the shift register unit provided by the present disclosure can be easily changed to all CMOS transistors, etc.

The shift register, gate drive circuit and display device provided by the present disclosure have the following advantages:

The shift register unit in the gate drive circuit controls the level signal of the first node through the third control module, so that the level signal of the first node remains as a high-level signal. Then, the second output module is turned off, and the first output module is always turned on, so that the output signal of the shift register unit continues to maintain a high-level signal, the frame data in the low refresh display area remains unchanged from the previous frame, the refresh rate in the low refresh display area is reduced, and the power consumption of the display area is reduced.

The above content is a further detailed description of the present disclosure in combination with a specific preferred embodiment, and it cannot be determined that the specific implementation of the present disclosure is limited to these descriptions. For those skilled in the art to which the present disclosure belongs, without departing from the concept of the present disclosure, several simple deductions or substitutions can be made, which should be regarded as belonging to the protection scope of the present disclosure.

1. A shift register unit, comprising:
an input module, configured to transmit an input signal of an input signal terminal to a first node in response to a first clock signal;
a first control module, configured to transmit a first voltage signal to the first node in response to a second clock signal;
a second control module, configured to transmit a second voltage signal to a second node in response to the first clock signal;
a first output module, configured to transmit the first voltage signal to an output signal terminal in response to a signal of the second node;
a second output module, configured to transmit the second clock signal to the output signal terminal in response to a signal of the first node;
a third control module, configured to transmit the first clock signal to the second node, or to transmit the first voltage signal to the first node in response to a control clock signal;
a first capacitor, connected between the first node and the output signal terminal; and
a second capacitor, connected between the first voltage signal terminal and the second node.

2. The shift register unit according to claim 1, wherein the input module comprises a first transistor, a control terminal of the first transistor is connected to a first clock signal line, a first terminal of the first transistor is connected to the input signal terminal, and a second terminal of the first transistor is connected to the first node.

3. The shift register unit according to claim 2, wherein the first control module comprises a second transistor and a third transistor; a control terminal of the second transistor is connected to a second clock signal line, and a second terminal of the second transistor is connected to the first node;
a control terminal of the third transistor is connected to the second node, a first terminal of the third transistor is connected to a first voltage signal line, and a second terminal of the third transistor is connected to the first terminal of the second transistor.

4. The shift register unit according to claim 3, wherein the second control module comprises a fourth transistor and a fifth transistor, a control terminal of the fourth transistor is connected to the first clock signal line, a first terminal of the fourth transistor is connected to a second voltage signal line, and a second terminal of the fourth transistor is connected to the second node;
a control terminal of the fifth transistor is connected to the first node, a first terminal of the fifth transistor is connected to a first output terminal of the third control module, and a second terminal of the fifth transistor is connected to the second node.

5. The shift register unit according to claim 4, wherein the first output module comprises a sixth transistor, a control terminal of the sixth transistor is connected to the second node, a first terminal of the sixth transistor is connected to the first voltage signal line, and a second terminal of the sixth transistor is connected to the output signal terminal.

6. The shift register unit according to claim 5, wherein the second output module comprises a seventh transistor, a control terminal of the seventh transistor is connected to the first node, a first terminal of the seventh transistor is connected to the second clock signal line, and a second terminal of the seventh transistor is connected to the output signal terminal.

7. The shift register unit according to claim 6, wherein the third control module comprises an eighth transistor and a ninth transistor, and the control clock signal comprises a third clock signal and a fourth clock signal; wherein,
a control terminal of the eighth transistor is connected to a third clock signal line, a first terminal of the eighth transistor is connected to the first clock signal line, and a second terminal of the eighth transistor is connected to the first terminal of the fifth transistor;
a control terminal of the ninth transistor is connected to a fourth clock signal line, a first terminal of the ninth transistor is connected to the first voltage signal line, and a second terminal of the ninth transistor is connected to the first node.

8. The shift register unit according to claim 7, wherein the first transistor to the ninth transistor are all PMOS transistors.

9. The shift register unit according to claim 7, wherein the third clock signal line and the fourth clock signal line are realized through a same signal line.

10. The shift register unit according to claim 9, wherein the first transistor to the seventh transistor are PMOS transistors, and the eighth transistor and ninth transistor are NMOS transistors.

11. The shift register unit according to claim 1, wherein the first clock signal and the second clock signal are pulse signals with a same frequency and opposite phases.

12. The shift register unit according to claim 7, wherein the third clock signal is at a low level and the fourth clock signal is at a high level in a high refresh display area;
in a first phase of a low refresh display area, the first clock signal is at a low level, the second clock signal is at a high level, the third clock signal is at a high level, and the fourth clock signal is at a high level; and
in a second phase of the low refresh display area, the first clock signal is at a high level, the second clock signal is at a low level, the third clock signal is at a high level, and the fourth clock signal is at a low level.

13. The shift register unit according to claim 1, wherein the first voltage signal is at a high level, the second voltage signal is at a low level, and the input signal is a low-level start pulse signal.

14. A gate drive circuit, comprising the shift register unit according to claim 1.

15. The gate drive circuit according to claim 14, wherein a plurality of the shift register units are electrically connected in a cascade manner, wherein an input signal terminal of a first-stage shift register unit is connected to a start pulse signal, and except for a last-stage shift register unit, an output signal terminal of each stage of the shift register unit is connected to an input signal terminal of a next-stage shift register unit.

16. A display device, comprising the gate drive circuit according to claim 14.

17. A display device, comprising the gate drive circuit according to claim 15.
